(19) United States
(12) Patent Application Publication
(10) Pub. No.: US 2012/0127660 A1
(43) Pub. Date: May 24, 2012

(54) CYLINDRICAL PACKAGES, ELECTRONIC APPARATUS INCLUDING THE SAME, AND METHODS OF FABRICATING THE SAME

(75) Inventors: Kang Won LEE, Namyangju-si (KR); Hyun Joo KIM, Icheon-si (KR); Gyujei LEE, Seoul (KR)

(73) Assignee: HYNIX SEMICONDUCTOR INC., Icheon-si (KR)

(21) Appl. No.: 13/298,512

(22) Filed: Nov. 17, 2011

(30) Foreign Application Priority Data
Nov. 19, 2010 (KR) 10-2010-0115716

(51) Int. Cl. H05K 7/20; H05K 3/30; H05K 1/11; H05K 1/02; H05K 1/18

(52) U.S. Cl. 361/689; 361/749; 361/783; 361/772; 29/837

(57) ABSTRACT

Cylindrical packages are provided. The cylindrical package includes a cylindrical substrate having a hollow region therein and at least one semiconductor chip mounted on an outer circumference of the cylindrical substrate. Related electronic products and related fabrication methods are also provided.

### CROSS-REFERENCES TO RELATED APPLICATIONS

The present application claims priority under 35 U.S.C 119(a) to Korean Application No. 10-2010-0115716, filed on Nov. 19, 2010, in the Korean intellectual property Office, which is incorporated herein by reference in its entirety.

### BACKGROUND

Exemplary embodiments of the present disclosure relate generally to semiconductor packages and methods of fabricating the same and, more particularly, to cylindrical packages, electronic apparatus including the same, and methods of fabricating the same.

Semiconductor chips including a plurality of integrated circuit may be easily damaged by external physical and/or chemical impacts. Thus, the semiconductor chips may not be used as semiconductor end products by themselves. Accordingly, the semiconductor chips may be encapsulated using one of various assembly processes. For example, the semiconductor chip may be mounted on a substrate (e.g., a lead frame or a printed circuit board) which can electrically connect the semiconductor chip to external devices. Further, the semiconductor chip mounted on the substrate may be packaged using a material such as an epoxy molding compound (EMC) material to protect the semiconductor chip from external moisture and/or external contaminants.

Some semiconductor packages may be configured to have a semiconductor chip mounted on a flat substrate and bonding wires (or bumps) electrically connecting the semiconductor chip to the flat substrate, in spite of the presence of substantial warpage of the semiconductor chip. In this case, physical stresses may be applied to the semiconductor chip and/or the substrate. However, with the development of information technology, electronic products having a curvature may be required. Thus, semiconductor packages including a semiconductor chip mounted on a non-flat substrate may be demanded in future.

### SUMMARY

Some exemplary embodiments are directed to cylindrical packages which is suitable for electronic products having a curvature.

Other exemplary embodiments are directed to methods of fabricating a cylindrical package which is suitable for electronic products having a curvature.

Still other exemplary embodiments are directed to electronic products including the cylindrical package.

In an exemplary embodiment, the cylindrical package includes a cylindrical substrate having a hollow region therein and at least one semiconductor chip mounted on an outer circumference of the cylindrical substrate.

The cylindrical substrate may be a flexible substrate.

The cylindrical substrate may include at least one of polyethylene terephthalate (PET), polyethylene naphthalate (PEN), polyether sulfone (PES), polyarylate (PAR), polycarbonate (PC), cycloolefin copolymer (COC), polystyrene (PS) and polyimide (PI).

The cylindrical package may further include bonding wires electrically connecting chip pads of the at least one semiconductor device to substrate pads of the cylindrical substrate. The cylindrical package may further include an adhesive agent between the outer circumference of the cylindrical substrate and a bottom surface of the at least one semiconductor chip.

The cylindrical package may further include an interconnection portion electrically connecting chip pads of the at least one semiconductor device to substrate pads of the cylindrical substrate. The interconnection portion may include a metal bump and a solder bump. The interconnection portion may include an anisotropic conductive film.

The cylindrical package may further include a molding material covering the at least one semiconductor chip.

In another exemplary embodiment, the electronic product includes a cylindrical package, and the cylindrical package includes a cylindrical substrate having a hollow region therein and at least one semiconductor chip mounted on an outer circumference of the cylindrical substrate.

The electronic product may further include a cooling medium that flows through the hollow region of the cylindrical package.

In yet another exemplary embodiment, the method includes forming circuit patterns on a flat flexible substrate having a first surface and a second surface opposite to the first surface, connecting both ends of the flexible substrate to form a cylindrical flexible substrate, and mounting at least one semiconductor chip on an outer circumference of the cylindrical flexible substrate.

The flexible substrate may include at least one of polyethylene terephthalate (PET), polyethylene naphthalate (PEN), polyether sulfone (PES), polyarylate (PAR), polycarbonate (PC), cycloolefin copolymer (COC), polystyrene (PS) and polyimide (PI).

Connecting both ends of the flexible substrate may include bonding both ends of the flexible substrate using an adhesive agent.

Connecting both ends of the flexible substrate may include bonding both ends of the flexible substrate using a fusion bonding technique.

One of both ends of the flexible substrate may have a female configuration and the other of both ends of the flexible substrate may have a male configuration.

Connecting both ends of the flexible substrate may include surrounding both ends of the flexible substrate with a bonding band.

The method may further include molding the at least one semiconductor chip after mounting the at least one semiconductor chip on the cylindrical substrate. The method may further include sawing the flexible substrate to form a plurality of cylindrical packages after molding the at least one semiconductor chip.

### BRIEF DESCRIPTION OF THE DRAWINGS

The above and other aspects, features and other advantages will be more clearly understood from the following detailed description taken in conjunction with the accompanying drawings, in which:

FIG. 1 is a cross sectional view illustrating a cylindrical package according to an exemplary embodiment of the present invention;

FIG. 2 is a cross sectional view illustrating a cylindrical package according to an exemplary embodiment of the present invention;

FIGS. 3A to 3D are cross sectional views illustrating various examples of interconnection portions of flip chips;

FIGS. 4A to 4E are drawings illustrating a method of fabricating a cylindrical package according to an exemplary embodiment of the present invention;

FIGS. 5A to 5F are cross sectional views illustrating various examples of methods of physically connecting both ends of a flexible substrate to each other;

FIG. 6 is a perspective view illustrating an electronic product including a cylindrical package according to an exemplary embodiment of the present invention; and

FIG. 7 is a horizontal cross sectional view taken along a line A-A′ of FIG. 6.

### DESCRIPTION OF SPECIFIC EMBODIMENTS

Exemplary embodiments will be described hereinafter in detail with reference to the accompanying drawings. Many different forms and embodiments are possible without deviating from the spirit and teachings of this disclosure and so the disclosure should not be construed as limited to the exemplary embodiments set forth herein. Rather, these exemplary embodiments are provided so that this disclosure will be thorough and complete, and will convey the scope of the disclosure to those skilled in the art. In the drawings, the sizes and relative sizes of layers and regions may be exaggerated for clarity. Like reference numbers refer to like elements throughout.

As used herein the term “and/or” includes any and all combinations of one or more of the associated listed items.

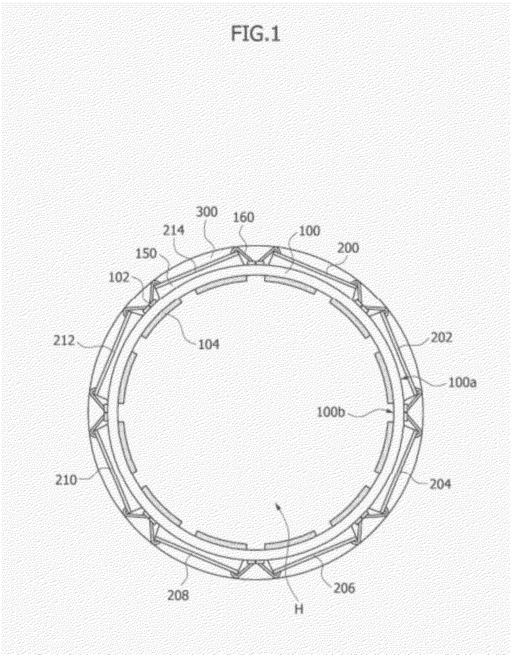

FIG. 1 is a cross sectional view illustrating a cylindrical package according to an exemplary embodiment of the present invention.

Referring to FIG. 1, a cylindrical package according to an exemplary embodiment of the present invention may include a substrate 100, one or more of a plurality of semiconductor chips 200, 202, 204, 206, 208, 210, 212 and 214 and a molding member 300.

The substrate 100 may be a cylindrical substrate having a hollow region H therein. As illustrated in FIG. 1, the substrate 100 may have a circular shape in a cross sectional view. However, the cross sectional view of the substrate 100 is not limited to the circular shape. For example, the substrate 100 may have an oval shape in a cross sectional view. The substrate 100 should be bent to have a closed loop shape such as a circular shape or an oval shape in a cross sectional view. Thus, the substrate 100 may include a flexible material. For example, the substrate 100 may include at least one of polyethylene terephthalate (PET), polyethylene naphthalate (PEN), polyether sulfone (PES), polyarylate (PAR), polycarbonate (PC), cycloolefin copolymer (COC), polystyrene (PS) and polyimide (PI). However, the substrate 100 is not limited to the above materials.

In an exemplary embodiment of the present invention, the substrate 100 may include a plurality of arc-shaped subsections that are connected to each other to constitute a cylindrical substrate having a closed loop shape in a cross sectional view. In this case, each of the arc-shaped subsections constituting the substrate 100 may not be a flexible material.

As described above, the cylindrical package may include the plurality of semiconductor chips 200, 202, 204, 206, 208, 210, 212 and 214. However, for the purpose of ease and convenience in explanation, the present exemplary embodiment will be described hereinafter with only one of the semiconductor chips, for example, the semiconductor chip 200. The semiconductor chip 200 may be a memory device, a logic device, a photoelectric conversion device or a power device. Also, the cylindrical package may include one or more of the memory device, the logic device, the photoelectric conversion device and the power device. The semiconductor device may include at least one passive element, for example, at least one resistor and/or at least one capacitor.

An adhesive agent 150 may be provided between a bottom surface of the semiconductor chip 200 and a portion of an outer circumference surface 100a of the substrate 100. The adhesive agent 150 may fix the semiconductor chip 200 to the substrate 100.

Further, the semiconductor chip 200 may be electrically connected to the substrate 100 through bonding wires 160. That is, the bonding wires 160 may electrically connect chip pads (not shown) of the semiconductor chip 200 to substrate pads 102 formed on the outer circumference surface 100a of the substrate 100. Connection pads 104 may be formed on an inner circumference surface 100b of the substrate 100. The connection pads 104 may be used to electrically connect the semiconductor chip 200 to another electronic product. The adhesive agent 150 may include a coating material or a double-sided tape. However, the adhesive agent 150 is not limited to the above listed materials. Any type of adhesive agent that fixes the semiconductor chip 200 to the substrate 100 can be used.

The semiconductor chip 200 may be covered with a molding material 300. The molding material 300 may protect the semiconductor chip 200 from an external environment. The molding material 300 may be an epoxy molding compound (EMC) material.

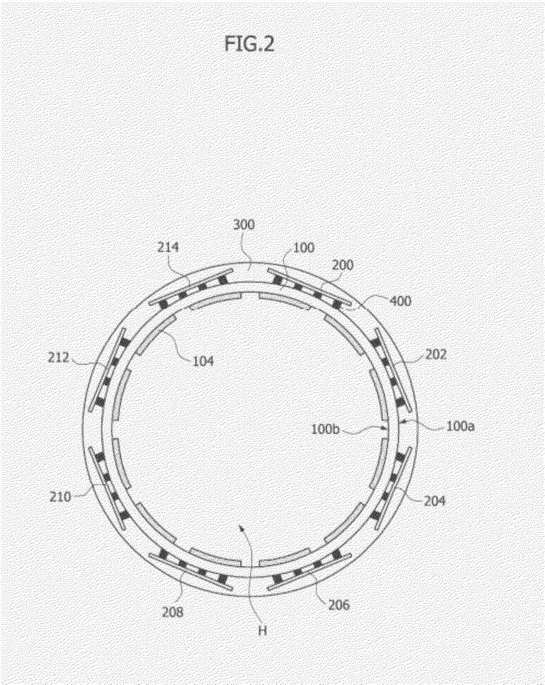

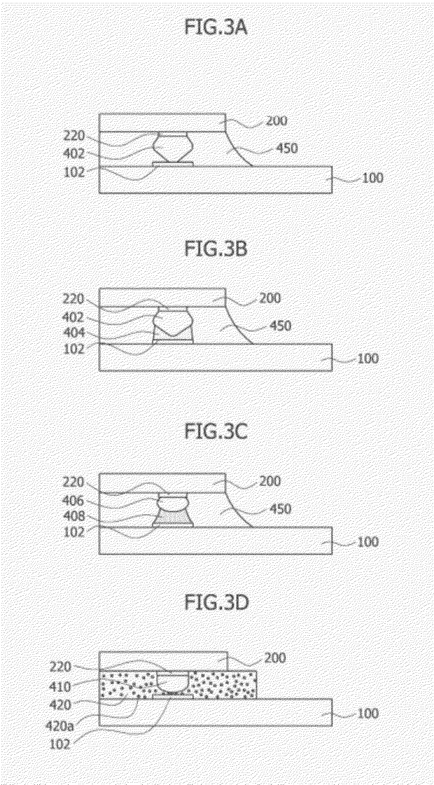

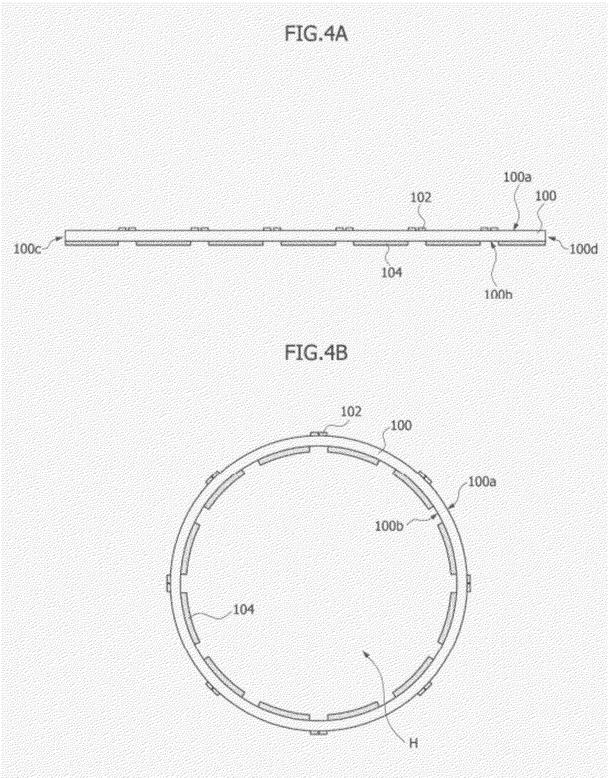

FIG. 2 is a cross sectional view illustrating a cylindrical package according to an exemplary embodiment of the present invention, and FIGS. 3A to 3D are cross sectional views illustrating various examples of interconnection portions of flip chip package.

Referring to FIGS. 2, 3A, 3B, 3C and 3D, a plurality of semiconductor chips 200, 202, 204, 206, 208, 210, 212 and 214 may be attached to an outer circumference surface 100a of a cylindrical substrate 100. The semiconductor chips 200, 202, 204, 206, 208, 210, 212 and 214 may be mounted on the outer circumference surface 100a using a flip chip bonding method. That is, each of the semiconductor chips 200, 202, 204, 206, 208, 210, 212 and 214 may be connected to the substrate 100 by an interconnection portion 400.

The interconnection portion 400 may include metal bumps 402 that electrically connect chip pads 220 of each of the semiconductor chips 200, 202, 204, 206, 208, 210, 212 and 214 to substrate pads 102 formed on the substrate 100, as illustrated in FIG. 3A. The cylindrical package may further include under-fill resin 450 filling spaces between the semiconductor chips 200, 202, 204, 206, 208, 210, 212 and 214 and the substrate 100. Each of the metal bumps 402 may be a single-layered bump or a multi-layered bump that includes at least one of gold (Au), silver (Ag), copper (Cu), aluminum (Al), nickel (Ni), tungsten (W), titanium (Ti), platinum (Pt), palladium (Pd), tin (Sn), lead (Pb), zinc (Zn), indium (In), cadmium (Cd), chrome (Cr) and molybdenum (Mo). Each of the metal bumps 402 may further include a conductive organic material. The metal bumps 402 may be formed using an electroless-plating process, an electro-plating process, an evaporation process or a sputtering process. Each of the metal bumps 402 may be a gold bump, a gold stud bump or a nickel bump. The gold bump may be formed using an electroless-plating process or an electro-plating process. Further, the gold bump may be formed of Cr/Cu, Cr/Cu/Au, TiW/Au or Ti/Au using an under bump metallurgy (UBM). Forming the gold stud bump may include forming a stud bump (e.g., a gold ball) on the chip pad 220 of each of the semiconductor chips 200, 202, 204, 206, 208, 210, 212 and 214 using a wire bonding machine. Thus, the gold stud bump may be formed without the use of the under bump metallurgy (UBM). The nickel bump may be formed using an electroless-plating process or an electro-plating process.

In some embodiments, conductive adhesive agent 404 may be provided between the metal bump 402 and the substrate pad 102, as illustrated in FIG. 3B. The conductive adhesive agent 404 may improve the adhesive strength between the metal bump 402 and the substrate pad 102. The cylindrical package may further include under-fill resin 450 filling spaces between the semiconductor chips 200, 202, 204, 206, 208, 210, 212 and 214 and the substrate 100.

In some embodiments, each of the interconnection portions 400 may include a solder bump 406 and a solder 408 that electrically connect the chip pad 220 to the substrate pad 102, as illustrated in FIG. 3C. The cylindrical package may further include under-fill resin 450 filling spaces between the semiconductor chips 200, 202, 204, 206, 208, 210, 212 and 214 and the substrate 100. The solder 408 may mean a metal alloy having a melting point which is equal to or lower than about 450 degrees Celsius. The solder bump 406 may be formed using an evaporation process, a vacuum metallizing process, an electro-plating process or a screen printing process, and an under bump metallurgy (UBM) may be additionally provided under the solder bump 406. The electro-plating process may use a eutectic solder, and the UBM may include a titanium-tungsten (TiW) alloy. The screen printing process may correspond to a method of forming a solder such as a Pb/In/Ag solder, a Sn/Pb/In solder or a Cu/Sb/Ag/Au solder through a stencil mask. The screen printing process may use an unleaded solder of a three or more component system. The screen printing process has an advantage of a simple process.

In some embodiments, each of the interconnection portions 400 may include a metal bump 410 and an anisotropic conductive film 420 that electrically connect the chip pad 220 to the substrate pad 102, as illustrated in FIG. 3D. The metal bump 410 may be a single-layered bump or a multi-layered bump that includes at least one of gold (Au), silver (Ag), copper (Cu), aluminum (Al), nickel (Ni), tungsten (W), titanium (Ti), platinum (Pt), palladium (Pd), tin (Sn), lead (Pb), zinc (Zn), indium (In), cadmium (Cd), chrome (Cr) and molybdenum (Mo). Each of the metal bumps 410 may further include a conductive organic material. The metal bumps 410 may be formed using an electroless-plating process, an electro-plating process, an evaporation process or a sputtering process. Each of the metal bumps 410 may be a gold bump, a gold stud bump or a nickel bump. The anisotropic conductive film 420 may contain a plurality of conductive particles 420a. If the anisotropic conductive film 420 may be heated and pressurized, the metal bump 410 may be electrically connected to the corresponding substrate pad 102 through the conductive particles 420a. The conductive particles 420a may include metal particles, plastic particles coated with metal, or conductive particles coated with insulation resin. The metal particles may include nickel particles, solder particle or silver particles, and the plastic particles may include carbon particles, polystyrene particles or epoxy resin particles. However, the conductive particles are not limited to the above listed materials. The anisotropic conductive film 420 may contain an adhesive agent that endows the anisotropic conductive film 420 with an adhesive property. The adhesive agent may include at least one of thermoplastic resin, thermosetting resin and ultraviolet curable resin. The thermoplastic resin may be polyethylene type resin or polypropylene type resin, and the thermosetting resin may include epoxy type resin, polyurethane type resin or acrylic type resin. However, the adhesive agent is not limited to the above listed materials.

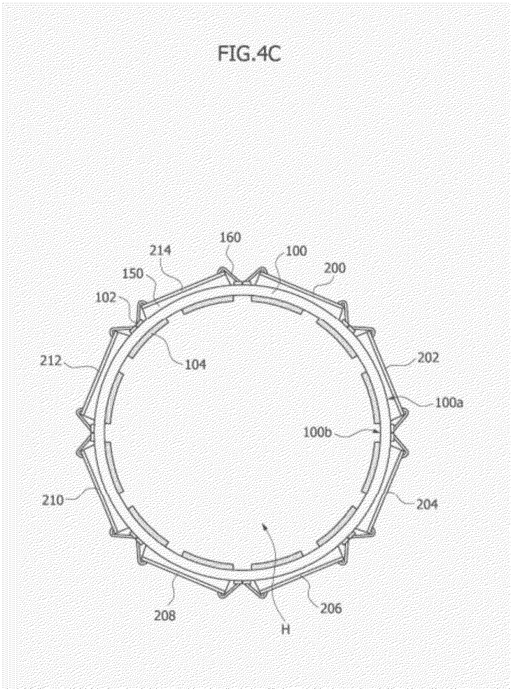

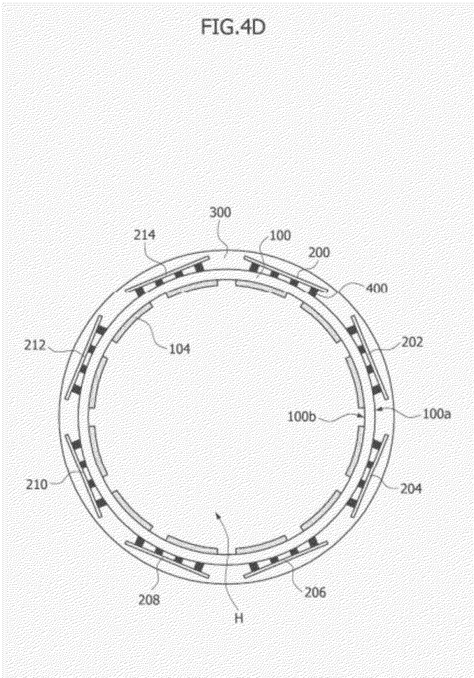

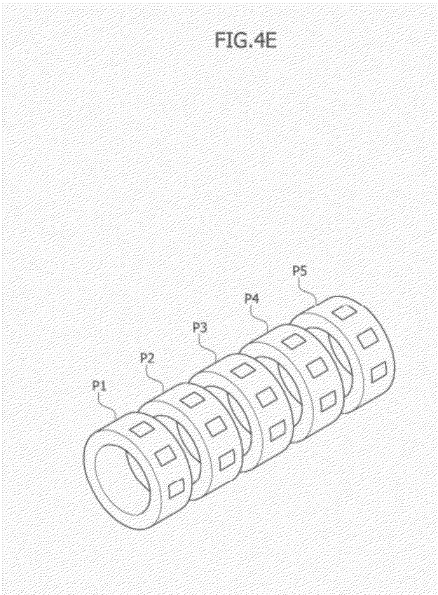

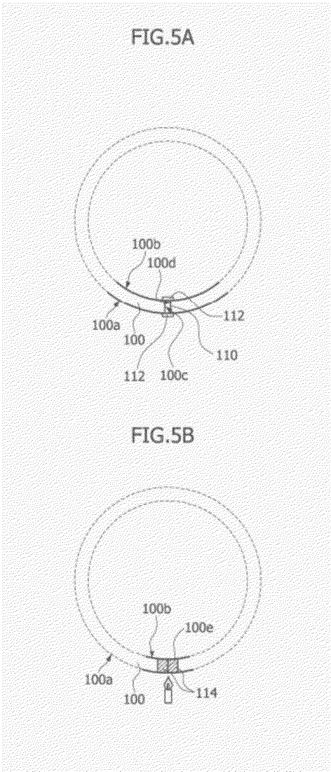

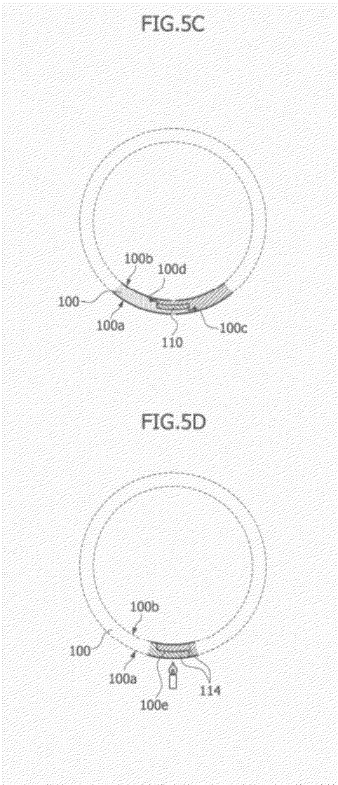

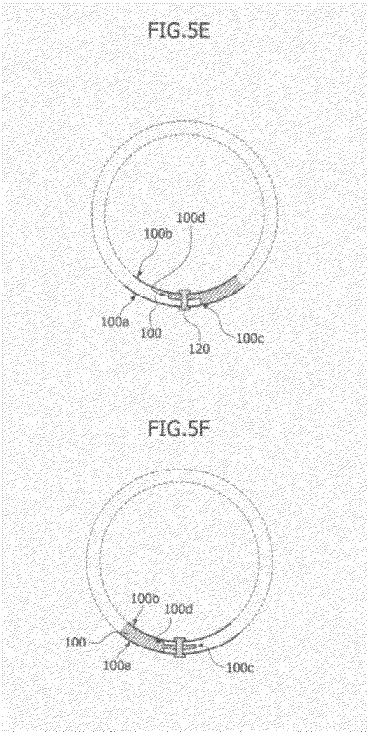

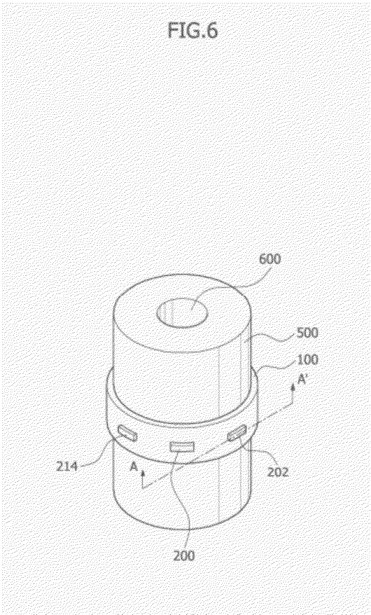

FIGS. 4A to 4E are drawings illustrating a method of fabricating a cylindrical package according to an exemplary embodiment of the present invention, and FIGS. 5A to 5F are cross sectional views illustrating various examples of methods of physically connecting both ends of a flexible substrate to each other.

Referring to FIG. 4A, circuit patterns, for example, through holes (not shown) and conductive pads may be formed in and on the substrate 100. The through holes and the conductive pads may be formed to electrically connect semiconductor chips to external electronic devices. For example, the conductive pads may include substrate pads 102 and connection pads 104. The substrate pads 102 may be formed on a first surface 100a of the substrate 100 and may be electrically connected to the semiconductor chips arranged on the first surface 100a, and the connection pads 104 may be formed on a second surface 100b of the substrate 100 opposite to the first surface 100a and may be electrically connected to the external electronic devices. The substrate 100 may be formed of at least one plastic material of polyethylene terephthalate (PET), polyethylene naphthalate (PEN), polyether sulfone (PES), polyarylate (PAR), polycarbonate (PC), cycloolefin copolymer (COC), polystyrene (PS) and polyimide (PI). However, the substrate 100 is not limited to the above listed plastic materials.

Referring to FIG. 4B and FIGS. 5A to 5F, the flat substrate 100 illustrated in FIG. 4A may be bent to physically connect both ends (first and second ends) of the substrate 100 to each other. As a result, the flat substrate 100 may be transformed into a cylindrical substrate 100 having a hollow region H therein.

In some embodiments, one end (e.g., the first end) 100c and the other end (e.g., the second end) 100d may be physically bonded to each other using an adhesive agent 110. Further, both ends (e.g., the first and second ends) 100c and 100d of the substrate 100 may be surrounded by a bonding band 112 to prevent the first and second ends from being detached to each other (refer to FIG. 5A).

In some embodiments, the first and second ends 100c and 100d may be in contact with each other and may be heated for a moment to physically connect them to each other. That is, the first and second ends 100c and 100d may be bonded to each other using a fusion bonding technique. In this case, the first and second ends 100c and 100d may be melted and bonded to each other, thereby forming a fusion bonding interface 100e between the first and second ends 100c and 100d. Further, a fusion zone 114 may be formed to be adjacent to the fusion bonding interface 100e (refer to FIG. 5B). The fusion zone 114 may correspond to a region that portions of the substrate 100 adjacent to the first and second ends 100c and 100d are fused and cooled down.

In some embodiments, each of the first and second ends 100c and 100d may include a structure having an enlarged surface area to enhance adhesive strength between the first and second ends 100c and 100d. Here, the first and second ends 100c and 100d may have complementary shapes. For example, the first end 100c may have a ‘└’-shaped sectional view and the second end 100d may have a ‘└’-shaped sectional view, as illustrated in FIG. 5C. The first and second ends 100c and 100d may be physically bonded to each other by an adhesive agent 110 disposed therebetween.

In some embodiments, the first end 100c may have a ‘└’-shaped sectional view and the second end 100d may have a ‘└’-shaped sectional view, as described with reference to FIG. 5C. further, the first and second ends 100c and 100d may be physically bonded to each other using the fusion bonding technique described with reference to FIG. 5B. Thus, a fusion bonding interface 110e may be formed between the first and second ends 100c and 100d, and a fusion zone 114 may be formed to be adjacent to the fusion bonding interface 100e (refer to FIG. 5D).

In some embodiments, the first end 100c may have a ‘└’-shaped sectional view and the second end 100d may have a ‘└’-shaped sectional view, as described with reference to FIG. 5C. Further, the first and second ends 100c and 100d may be physically combined with each other using a fixing member 120 (refer to FIG. 5E).

In some embodiments, the first end 100c may have a female configuration and the second end 100d may have a male configuration. Alternatively, the first end 100c may have a male configuration and the second end 100d may have a female configuration. One (having the male configuration) of the first and second ends 100c and 100d may be inserted into the other (having the female configuration) to combine with each other. In addition, the first and second ends 100c and 100d may be more tightly combined with each other using a fixing member 120 (refer to FIG. 5F).

In other embodiments, the bonding method of the first and second ends 100c and 100d may be performed using a combination of the embodiments described with reference to FIGS. 5A to 5F. For example, after the first and second ends 100c and 100d having male and female configurations are combined with each other, the first and second ends 100c and 100d may be more tightly bonded using the fusion bonding technique described with reference to FIG. 5B, using the bonding band 112 described with reference to FIG. 5A, and/or using the fixing member 120 described with reference to FIG. 5E.

Referring to FIG. 4C, at least one semiconductor chip, for example, a plurality of semiconductor chips 200, 202, 204, 206, 208, 210, 212 and 214 may be mounted on an outer circumference surface 100a of the cylindrical substrate 100. The at least one semiconductor chip may be mounted on the outer circumference surface 100a using a wire bonding technique or a flip chip bonding technique. Specifically, a rotation axis (not shown) may be installed in the hollow region H of the cylindrical substrate 100, and the at least one semiconductor chip may be mounted on the outer circumference surface 100a of the cylindrical substrate 100 while the cylindrical substrate 100 rotates. Alternatively, the at least one semiconductor chip may be mounted on the outer circumference surface 100a of the cylindrical substrate 100 using a rotating chip mount apparatus without rotation of the cylindrical substrate 100.

Referring to FIG. 4D, the at least semiconductor chip may be covered with a molding material. The molding material may include epoxy resin. The molding material may further include at least one of a hardening agent, a hardening accelerator, a filler and other additive agents. The epoxy resin may include at least one of bisphenol type epoxy, phenol novolac type epoxy, cresol novolac type epoxy, multifunctional epoxy, amine type epoxy, heterocycle containing epoxy, substitutional epoxy, naphthol type epoxy and derivatives thereof. However, the epoxy resin may not be limited to the above listed materials. The hardening agent may include at least one of an amine hardening agent, an acid anhydride hardening agent, a polyamide resin, a polysulfide resin and a phenol resin. However, the hardening agent may not be limited to the above listed materials. The hardening accelerator may be used to accelerate a hardening reaction between the epoxy resin and the hardening agent, and any material accelerating the hardening reaction can be used. For example, the hardening accelerator may be an amine compound material (e.g., tri-ethylamine, benzyl di-methylamine, a-methyl benzyldimethylamine or 1,8-diazabicyclo-undecene-7), an imidazole compound material (e.g., 2-methyl-imidazole, 2-phenilimidazole or 2-phenil-4-methylimidazole) or an organic phosphorus compound material (e.g., salicylic acid, phenol, triphenilphosphine, tributhylphosphine, tri(p-methylphenil)phosphine, triphenilphosphine triphenilborate or tetraphenilphosphine tetraphenilborate). However, the hardening accelerator may not be limited to the above listed materials. The filler may include at least one of an organic filler and an inorganic filler. The inorganic filler may include at least one of talc, sand, silica, calcium carbonate, quartz, glass fiber, graphite, alumina, stibium oxide, BaTiO₃ and bentonite. The organic filler may include at least one of phenol resin and ureaformaldehyde. However, the filler may not be limited to the above listed materials. The molding material may further include aerosol (silica having a colloid phase) and/or bentonite type clayish filler to endow the epoxy resin with thixotropic property. The other additive agents may include a coloring agent (e.g., organic dye or inorganic dye), a coupling agent and/or a defoaming agent.

Referring to FIG. 4E, a singulation process may be performed to the cylindrical substrate including the molded semiconductor chips. The singulation process corresponds to a sawing process that separates the cylindrical substrate including the molded semiconductor chips into a plurality of cylindrical packages P1, P2, P3, P4 and P5. In the event that only a single semiconductor chip is mounted on the cylindrical substrate 100, the singulation process may be omitted.

According to an exemplary embodiment of the present invention illustrated in FIGS. 4A to 4E, the at least one semiconductor chip is mounted on the cylindrical substrate 100 after formation of the cylindrical substrate 100. However, the inventive concept is not limited to the exemplary embodiment illustrated in FIGS. 4A to 4E. For example, after the at least one semiconductor chip is mounted on a flat flexible substrate 100, the flat flexible substrate 100 may be bent to form the cylindrical substrate 100 having a closed loop shape such as a circular shape or an oval shape in a cross sectional view.

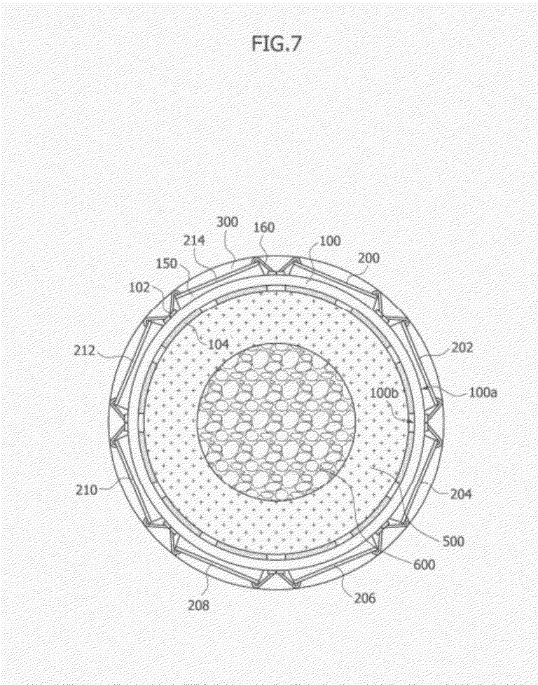

FIG. 6 is a perspective view illustrating an electronic product including a cylindrical package according to an exemplary embodiment of the present invention, and FIG. 7 is a horizontal cross sectional view taken along a line A-A′ of FIG. 6.

Referring to FIGS. 6 and 7, an electronic module 500 may be arranged in an inside region (e.g., a hollow region) of a cylindrical package according to an exemplary embodiment of the present invention. The electronic module 500 may be electrically connected to the cylindrical package. The electronic module 500 may also have a hollow region therein, and a cooling medium 600 may flow through the hollow region of the electronic module 500 to cool down the cylindrical package and the electronic module 500 which are heated up. Descriptions to the cylindrical package will be omitted hereinafter since the cylindrical package has been already described in the previous embodiment. The cooling medium 600 may include water such as de-ionized water (or distilled water) or other coolants.

According to the exemplary embodiments set forth above, a cylindrical package may be provided to include a cylindrical substrate and at least one semiconductor chip mounted on outer circumference of the cylindrical substrate. Thus, even though the semiconductor chip is warped, the cylindrical package may accept warpage of the semiconductor chip to reduce physical stress between semiconductor chip and the cylindrical substrate. As a result, the cylindrical package may increase the design flexibility of the semiconductor chip and may be employed in electronic products having a curvature

The exemplary embodiments of the inventive concept have been disclosed above for illustrative purposes. Those skilled in the art will appreciate that various modifications, additions and substitutions are possible, without departing from the scope and spirit of the inventive concept as disclosed in the accompanying claims.

What is claimed is:

1. A cylindrical package comprising:
a cylindrical substrate having a hollow region therein; and
at least one semiconductor chip mounted on an outer circumference of the cylindrical substrate.

2. The cylindrical package of claim 1, wherein the cylindrical substrate is a flexible substrate.

3. The cylindrical package of claim 1, wherein the cylindrical substrate includes at least one of polyethylene terephthalate (PET), polyethylene naphthalate (PEN), polyether sulfone (PES), polyarylate (PAR), polycarbonate (PC), cycloolefin copolymer (COC), polystyrene (PS) and polyimide (PI).

4. The cylindrical package of claim 1, further comprising bonding wires electrically connecting chip pads of the at least one semiconductor device to substrate pads of the cylindrical substrate.

5. The cylindrical package of claim 4, further comprising an adhesive agent between the outer circumference of the cylindrical substrate and a bottom surface of the at least one semiconductor chip.

6. The cylindrical package of claim 1, further comprising an interconnection portion electrically connecting chip pads of the at least one semiconductor device to substrate pads of the cylindrical substrate.

7. The cylindrical package of claim 6, wherein the interconnection portion includes a metal bump and a solder bump.

8. The cylindrical package of claim 6, wherein the interconnection portion includes an anisotropic conductive film.

9. The cylindrical package of claim 1, further comprising a molding material covering the at least one semiconductor chip.

10. An electronic product comprising:
a cylindrical package,
wherein the cylindrical package comprises:
a cylindrical substrate having a hollow region therein;
and
at least one semiconductor chip mounted on an outer circumference of the cylindrical substrate.

11. The electronic product of claim 10, further comprising a cooling medium flowing through the hollow region of the cylindrical package.

12. A method of fabricating a cylindrical package, the method comprising:
forming circuit patterns on a flat flexible substrate having a first surface and a second surface opposite to the first surface;
connecting both ends of the flexible substrate to form a cylindrical flexible substrate; and
mounting at least one semiconductor chip on an outer circumference of the cylindrical flexible substrate.

13. The method of claim 12, wherein the flexible substrate includes at least one of polyethylene terephthalate (PET), polyethylene naphthalate (PEN), polyether sulfone (PES), polyarylate (PAR), polycarbonate (PC), cycloolefin copolymer (COC), polystyrene (PS) and polyimide (PI).

14. The method of claim 12, wherein connecting both ends of the flexible substrate includes bonding both ends of the flexible substrate using an adhesive agent.

15. The method of claim 12, wherein connecting both ends of the flexible substrate includes bonding both ends of the flexible substrate using a fusion bonding technique.

16. The method of claim 12, wherein one of both ends of the flexible substrate has a female configuration and the other of both ends of the flexible substrate has a male configuration.

17. The method of claim 12, wherein the both ends of the flexible substrate have complementary shapes.

18. The method of claim 12, wherein connecting both ends of the flexible substrate includes surrounding both ends of the flexible substrate with a bonding band.

19. The method of claim 12, further comprising molding the at least one semiconductor chip after mounting the at least one semiconductor chip on the cylindrical substrate.

20. The method of claim 19, further comprising sawing the flexible substrate to form a plurality of cylindrical packages after molding the at least one semiconductor chip.
